(19) United States
(12) Patent Application Publication
(10) Pub. No.: US 2014/0373913 A1
(43) Pub. Date: Dec. 25, 2014

(54) SOLAR CELL METALLIZATIONS CONTAINING ORGANOZINC COMPOUND

(71) Applicant: Heraeus Precious Metals North America Conshohocken LLC, West Conshohocken, PA (US)

(72) Inventors: Yi Yang, San Diego, CA (US); Srinivasan Sridharan, Strongsville, OH (US); Aziz S. Shaikh, San Diego, CA (US); Kenneth A. Clark, Chester Township, OH (US)

(21) Appl. No.: 14/366,121

(22) PCT Filed: Jan. 16, 2013
(86) PCT No.: PCT/US2013/021625

§ 371 Date: Jun. 17, 2014

Related U.S. Application Data
(60) Provisional application No. 61/587,804, filed on Jan. 18, 2012.

(51) Int. Cl. H01L 31/0224

(52) U.S. Cl. CPC H01L 31/022425
USPC 136/256; 252/514; 438/98

(57) ABSTRACT

Paste compositions, methods of making paste compositions, contacts, and methods of making contacts are disclosed. The paste compositions include a solid portion and a vehicle system. The solid portion includes a conductive metal component and a glass binder. The vehicle system includes organometallic compound containing zinc. The organometallic compounds containing zinc can be dissolved in the vehicle system and the vehicle system does not include particles that contain zinc. The paste compositions can be used to form contacts in solar cells or other related components.

### TECHNICAL FIELD

The subject disclosure generally relates to paste compositions, methods of making a paste composition, contacts, methods of making a contact which can be used in solar cells as well as other related components.

### BACKGROUND

Solar cells are generally made of semiconductor materials, such as silicon (Si), which convert sunlight into useful electrical energy. Solar cells are typically made of thin wafers of Si in which the required PN junction is formed by diffusing phosphorus (P) from a suitable phosphorus source into a P-type Si wafer. The side of silicon wafer on which sunlight is incident is in general coated with an anti-reflective coating (ARC) to prevent reflective loss of incoming sunlight, and thus to increase the efficiency of the solar cell. A two dimensional electrode grid pattern known as a front contact makes a connection to the N-side of silicon, and a coating of aluminum (Al) on the other side (back contact) makes connection to the P-side of the silicon. These contacts are the electrical outlets from the PN junction to the outside load.

Front contacts of silicon solar cells are formed by screen-printing a thick film paste. Typically, the paste contains approximately fine silver particles, glass and organics. After screen-printing, the wafer and paste are fired in air, typically at furnace set temperatures. During the firing, glass softens, melts, and reacts with the anti-reflective coating, etches the silicon surface, and facilitates the formation of intimate silicon-silver contact. Silver deposits on silicon as islands. The shape, size, and number of silicon-silver islands determine the efficiency of electron transfer from silicon to the outside circuit.

### SUMMARY

The following presents a simplified summary of the invention in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

In accordance with one aspect, a paste composition is provided. More particularly, in accordance with this aspect, the paste composition includes a solid portion and a vehicle system. The solid portion includes an electrically conductive metal component at about 70 wt % or more and about 99.5 wt % or less of the solid portion and a glass binder containing one or more glass frits at about 0.5 wt % or more and about 30 wt % or less of the solid portion. The vehicle system includes an organometallic compound containing zinc.

In accordance with another aspect, a method of making a paste composition is provided. More particularly, in accordance with this aspect, the method involves combining a conductive metal component, a glass binder, a vehicle system including a vehicle and an organometallic compound containing zinc, and dispersing the conductive metal and the glass binder in the vehicle system.

In accordance with yet another aspect, a contact formed on a silicon solar cell is provided. More particularly, in accordance with this aspect, the contact is formed by firing a paste composition including a solid portion and a vehicle system. The solid portion includes a conductive metal component at about 70 wt % or more and about 99.5 wt % or less of the solid portion and a glass binder containing one or more glass frits at about 0.5 wt % or more and about 30 wt % or less of the solid portion. The vehicle system includes an organometallic compound containing zinc.

In accordance with still yet another aspect, a method of forming a solar cell contact is provided. More particularly, in accordance with this aspect, the method involves applying a paste composition to a silicon substrate and heating the paste to sinter metal components and fuse glass fits. The paste includes a solid portion and a vehicle system, the solid portion including a conductive metal component at about 70 wt % or more and about 99.5 wt % or less of the solid portion and a glass binder including one or more glass frits at about 0.5 wt % or more and about 30 wt % or less of the solid portion. The vehicle system includes an organometallic compound containing zinc. In addition to organometallic zinc, other organo-metallic additives especially Mn, Co, Fe, Cu, Ni, Ta, Ti, and V, can be added.

To the accomplishment of the foregoing and related ends, the invention, then, involves the features hereinafter fully described and particularly pointed out in the claims. The following description and the annexed drawings set forth in detail certain illustrative embodiments of the invention. These embodiments are indicative, however, of but a few of the various ways in which the principles of the invention can be employed. Other objects, advantages and novel features of the invention will become apparent from the following detailed description of the invention when considered in conjunction with the drawings.

### BRIEF DESCRIPTION OF THE DRAWINGS

FIGS. 1A-1E illustrate a process flow diagram schematically illustrating a process of making a contact in a solar cell in accordance with an aspect of the subject invention. Reference numerals shown in FIGS. 1A-1E are explained below.

10: p-type silicon substrate

20: n-type diffusion layer

30: front side passivation layer/anti-reflective coating

40: p+ layer (back surface field (BSF))

70: first paste formed on backside

71: back electrode formed by firing first paste 70

80: second paste formed on backside

81: back electrode formed by firing second paste 80

500: front side paste

501: front electrode after firing paste 500 through ARC

### DETAILED DESCRIPTION

The invention provides paste compositions including a solid portion and a vehicle system, the solid portion including an electrically conductive metal component and a glass binder and the vehicle system including an organometallic compound containing zinc. The paste compositions can be used to form contacts in solar cells as well as other related components. The contacts can be formed by applying the paste composition to a silicon substrate and heating the paste to sinter the conductive metal and fuse the glass frit. The paste compositions can provide one or more of the following advantages: improved adhesion, improved thermal expansion matching, and improved electrical properties. The solid portion of the paste composition is considered to be the conductive metal, the glass binder, other additives including crystallization materials, reducing agents, and the metals, taken together.

In one embodiment, the paste compositions can be used to make front contacts for silicon-based solar cells to collect current generated by exposure to light. In another embodiment, the paste compositions can be used to make back contacts for silicon-based solar cells. While the paste is generally applied by screen-printing, methods such as inkjet printing, spraying, extrusion, pad printing, stencil printing and hot melt printing may also be used. Solar cells with screen-printed front contacts are fired to relatively low temperatures (550° C. to 850° C. wafer temperature; furnace set temperatures of 650° C. to 1000° C.) to form a low resistance contact between the N-side of a phosphorus doped silicon wafer and a paste. Methods for making solar cells are also envisioned herein.

In another embodiment, in addition to organo-metallic zinc, other organo-metallic additives whose metal can be selected from Mn, Co, Fe, Cu, Ni, Ta, Ti, and V can be added.

Conductive Metal Component

The solid portion can contain any suitable conductive metal component in any suitable form. Examples of conductive metals include silver and nickel. The solid portion can include silver, nickel, or combinations of silver and nickel. The source of the silver in the conductive metal component can be one or more fine particles or powders of silver metal, or alloys of silver. A portion of the silver can be added as silver oxide (Ag₂O) or as silver salts such as AgNO₃, Ag₃PO₄, AgOOCCH₃ (silver acetate), silver acrylate or silver methacrylate. Specific examples of silver particles include spherical silver powder Ag3000-1, de-agglomerated silver powder SFCGED, silver flake SF-23, silver powder Ag 7000-35, and colloidal silver RDAGCOLB, all commercially available from Ferro Corporation, Cleveland, Ohio.

The source of the nickel in the conductive metal component can be one or more fine particles or powders of nickel metal, or alloys of nickel. A portion of the nickel can be added as organo-nickel. Specific organo-nickel examples are nickel acetylacetonate, nickel HEX-CEM from OMG.

In one embodiment, the conductive metal component can be coated with various materials such as phosphorus. Alternately, the conductive metal component can be coated on glass. Or silver oxide and/or nickel oxide can be dissolved in the glass during the glass melting/manufacturing process. The particles of the conductive metal component used in the paste can be spherical, flaked, colloidal, irregular shaped, amorphous, or combinations thereof.

The paste composition can include any of the aforementioned conductive metal components. In one embodiment, the solid portion of the paste contains irregular or spherical metal particles at about 70 wt % or more and about 99.5 wt % or less of the solid portion and metal flakes at about 0 wt % or more and about 29.5 wt % or less of the solid portion. In another embodiment, the solid portion of the paste contains metal flakes at about 70 wt % or more and about 99 wt % or less of the solid portion and colloidal metal at about 0.5 wt % or more and about 29.5 wt % or less of the solid portion. In another embodiment, the solid portion of the paste contains amorphous metal particles at about 70 wt % or more and about 99 wt % or less of the solid portion, metal flakes at about 0 wt % or more and about 29 wt % or less of the solid portion, and colloidal metal at about 0.5 wt % or more and about 29.5 wt % or less of the solid portion.

The solid portion of the paste composition generally contains conductive metal components at any suitable amount so long as the paste can provide electrical conductivity. In one embodiment, the solid portion contains conductive metal components at about 70 wt % or more and about 99.5 wt % or less of the solid portion. In another embodiment, the solid portion contains conductive metal components at about 75 wt % or more and about 98 wt % or less of the solid potion. In yet another embodiment, the solid portion contains conductive metal components at about 80 wt % or more and about 97 wt % or less of the solid portion.

The particles of the conductive metal components can have any suitable size. In one embodiment, the particles have a median particle size of about 0.05 microns or more and about 10 microns or less. In another embodiment, the particles have a median particle size of about 0.05 microns or more and about 5 microns or less. In yet another embodiment, the particles have a median particle size of about 0.05 microns or more and about 2.5 micron or less. In another embodiment, the particles have a specific surface area of about 0.01 to 10 g/m². In another embodiment, the particles have a specific surface area of about 0.1 to 5 g/m². In another embodiment, the particles have a specific surface area of about 0.2 to 4 g/m². In another embodiment, the particles have a specific surface area of about 0.2 to 3.5 g/m².

Glass Component

The glass component can contain any suitable one or more of glass frits. The glass frits used herein are not critical and the paste composition can contain any suitable glass frits. As an initial matter, the glass fits used in the pastes herein can intentionally contain lead and/or cadmium, or they can be devoid of intentionally added lead and/or cadmium. In one embodiment, the glass frit is a substantially lead-free glass frit. The glasses can be partially crystallizing or non-crystallizing Partially crystallizing glasses are preferred. The details of the composition and manufacture of the glass frits can be found in, for example, commonly-assigned U.S. Patent Application Publication. Nos. 2006/0289055 and 2007/0215202, which are hereby incorporated by reference.

The paste composition can include any suitable glass frit. The following tables set forth glass frit compositions useful in the practice of the invention. An entry such as Sb₂O₅+V₂O₅ means that Sb₂O₅ or V₂O₅ or a combination of the two is present in the specified amount.

TABLE 1
Lead based glass frit composition
in weight percent of total glass component.

| | Glass Composition |
|---|---|
| Constituent | I |
| PbO | 55-88 |
| (PbO + Bi₂O₃) | 55-90 |
| SiO₂ | 0.5-20 |
| Al₂O₃ + B₂O₃ | 0.5-24 |
| ZnO | 0-22 |
| Ta₂O₅ | 0-5 |
| ZrO₂ | 0-5 |
| P₂O₅ | 0-5 |
| Li₂O + K₂O + Na₂O | 0-10 |
| Fe₂O₃ + Co₂O₃ + CuO + MnO₂ | 0-15 |

TABLE 2
Lead free bismuth glass frit composition in weight
percent of total glass component.

| | Glass Composition |
|---|---|
| Constituent | II |
| Bi₂O₃ | 65-90 |
| Al₂O₃ + B₂O₃ | 0.5-24 |
| SiO₂ | 0-20 |
| ZnO | 0-13 |
| K₂O | 0-12 |
| LiO₂ | 0-5 |
| Na₂O | 0-5 |
| Nb₂O₅ | 0-5 |
| Fe₂O₃ + Co₂O₃ + CuO + MnO₂ | 0-15 |

TABLE 3
Lead free and bismuth free glass frit composition
in weight percent of total glass component.

| | Glass Composition |
|---|---|
| Constituent | III |
| B₂O₃ + SiO₂ | 30-62 |
| ZnO | 0-34 |
| TiO₂ | 0-22 |
| LiO₂ | 0-6 |
| Na₂O | 0-23 |
| K₂O | 0-13 |
| P₂O₅ | 0-5 |
| Sb₂O₅ + V₂O₅ | 0-13 |
| ZrO₂ | 0-5 |
| F | 0-5 |
| Fe₂O₃ + Co₂O₃ + CuO + MnO₂ | 0-15 |

The solid portion of the paste composition can contain any suitable amount of the glass component. In one embodiment, the solid portion contains the glass binder at about 0.5 wt % or more and about 30 wt % or less of the solid portion. In another embodiment, the solid portion contains the glass component at about 2 wt % or more and about 15 wt % or less of the solid portion. In yet another embodiment, the solid portion contains the glass component at about 2 wt % or more and about 10 wt % or less of the solid portion. In yet another embodiment, the solid portion contains the glass component at about 2 wt % or more and about 7 wt % or less of the solid portion. In yet another embodiment, the solid portion contains the glass component at about 1 wt % or more and about 6 wt % or less of the solid portion.

The particles of the glass frit components can have any suitable size. In one embodiment, the particles have a median particle size of about 0.1 microns or more and about 10 microns or less. In another embodiment, the particles have a median particle size of about 0.5 microns or more and about 2.5 micron or less.

In one embodiment, the glass compound includes a glass frit including: 55-88 wt % PbO, 0.5-15 wt % SiO₂, and 1-11 wt % Al₂O₃. The glass frit can further includes 0.1-5 wt % (P₂O₅+Ta₂O₅). In another embodiment, the glass compound includes a glass frit including: 65-90 wt % Bi₂O₃, 0.5-20 wt % SiO₂, and 2-11 wt % B₂O₃. In still another embodiment, the glass compound includes a glass fit including: 30-62 wt % (B₂O₃+SiO₂), 2-22 wt % TiO₂, and 2-35 wt % (Li₂O+Na₂O+K₂O). In certain embodiments, the combined total of Al₂O₃+B₂O₃ can be 0.5 to 24 wt %. The glass fit can further include 0.1-13 wt % (V₂O₅+Sb₂O₅).

Vehicle System

The vehicle system includes a vehicle and an organometallic compound containing zinc. The organometallic compounds containing zinc may be referred to as organozinc compounds. In one embodiment, the organozinc compound is fully dissolved in the vehicle. The term “fully dissolved” means that the vehicle system does not contain any particles (e.g., metal particles or metal oxide particles) and therefore no particles are visible to the naked eye or under the microscope. The organozinc compound is fully dissolved into the vehicle until no particles are visible to the naked eye or under the microscope. The vehicle system is free of any particles (e.g., free of metal particles and/or metal oxide particles). In another embodiment, the term “fully dissolved” means that the vehicle system does not contain any particles that contain zinc and therefore no zinc-containing particles are visible to the naked eye or under the microscope. The vehicle system is free of solid particles that contain zinc. The vehicle system can contain other zinc-containing compounds as long as the zinc-containing compounds are fully dissolved in the vehicle.

In one embodiment, the vehicle system is an organic vehicle system. The organic vehicle system includes organic solvents as a vehicle and organozinc compounds, but does not include inorganic materials such as inorganic solvent and particles of Zn, metal oxides of Zn (e.g., ZnO), and particles of any inorganic compounds that can generate metal oxides of Zn upon firing.

In one embodiment, the paste composition, the solid portion, and/or the vehicle system do not include particles that contain zinc. For example, the paste composition, the solid portion, and/or the vehicle system do not include particles of Zn, metal oxides of Zn (e.g., ZnO), and any solid compound that can generate metal oxides of Zn upon firing. The paste composition, prior to firing, can include any suitable amount of organometallic compound containing zinc. In one embodiment, the paste composition includes the organozinc compounds at about 0.05 wt % or more and about 30 wt % or less of the paste composition. In another embodiment, the paste composition includes the organozinc compounds at about 0.5 wt % or more and about 20 wt % or less of the paste composition. In yet another embodiment, the paste composition includes the organozinc compounds at about 0.5 wt % or more and about 10 wt % or less of the paste composition. The paste composition, after firing, can contain any suitable amount of metal or metal oxide of zinc. In one embodiment, the paste composition after firing contains zinc at about 0.001 wt % or more and about 20 wt % or less of the paste composition. In another embodiment, the paste composition contains zinc at about 0.01 wt % or more and about 15 wt % or less of the paste composition. In yet another embodiment, the paste composition contains zinc at about 0.05 wt % or more and about 10 wt % or less of the paste composition.

Organometallic Compound Containing Zinc

The vehicle system includes one or more organometallic compounds containing zinc. The organozinc compound is a compound where zinc is bound to any suitable organic moiety. For example, the organozinc compound is an organic compound containing zinc, carbon, and/or nitrogen in the molecule. Any suitable organozinc compounds can be used as long as the organozinc compound can be fully dissolved in a vehicle.

The organozinc compound is a compound that generates zinc oxides upon firing or sintering. Generally speaking, the organozinc compound can be described as follows: Znₓ-(Bridging Atom)-(Organic Moiety) wherein the bridging atom is nitrogen, carbon, sulfur, or oxygen. The organozinc compounds can include any suitable organic moieties in its compound. In one embodiment, the organic moiety includes carbon atoms. Examples of organic moieties include linear or branched, saturated or unsaturated, aliphatic, alicyclic, aromatic, araliphatic, halogenated or otherwise substituted, optionally having one or more heteroatoms such as O, N, S, or Si, and include hydrocarbon moieties such as alkyl, alkyloxy, alkylthio, or alkylsilyl moieties.

In one embodiment, organozinc compounds contain carbon to zinc chemical bonds. The oxidation state of zinc of the organozinc compounds is +2. Examples of such organozinc compounds include organozinc halides R—Zn—X with X a halogen atom, diorganozincs R—Zn—R, and lithium zincates or magnesium zincates M⁺RZn⁻ with M lithium or magnesium, where R is any suitable organic moieties such as an alkyl or aryl group.

Examples of organozinc compounds include zinc alkyls and zinc alkoxides. The alkyl moiety and the alkoxide moiety can have a branched or unbranched alkyl group of, for example, 1 to 20 carbon atoms. Specific examples of zinc alkyls include dimethylzinc, diethylzinc, dibutylzinc, dihexylzinc, didecylzinc, and didodecylzinc. Specific examples of zinc alkoxides include zinc methoxides, zinc ethoxides, zinc propoxide, zinc butoxide, zinc 2-ethyl hexanote, and zinc neodocanoate. Other examples of organozinc compounds include diphenylzinc, dibenzylzinc, zinc acetates, zinc acrylates, zinc formates, zinc lactate, zinc stearate, and zinc acetylacetonate. Yet other examples of organozinc compounds include zinc mercaptides, zinc mercaptocarboxylates, and zinc mercaptocarboxylic esters.

The vehicle system can include any suitable amount of organozinc compounds. In one embodiment, the vehicle system contains the organozinc compounds at about 0.01 wt % or more and about 90 wt % or less of the vehicle system. In another embodiment, the vehicle system contains the organozinc compounds at about 0.1 wt % or more and about 80 wt % or less of the vehicle system. In yet another embodiment, the vehicle system contains the organozinc compounds at about 0.5 wt % or more and about 70 wt % or less of the vehicle system.

Vehicle

The vehicle system includes a vehicle that dissolves the organozinc compounds. The vehicle typically includes a solvent (e.g., organic solvent and inorganic solvent). The vehicle can include any suitable solvent as long as the solvent can dissolve organozinc compounds. Examples of solvents include alcohols, esters, ethers, and terpenes.

The vehicle typically includes the solvent and a resin dissolved in the solvent. In one embodiment, the vehicle is a solvent solution containing both resin and a thixotropic agent. In particular, the solvent includes (a) at least about 50 wt % organic solvent; (b) up to about 15 wt % of a thermoplastic resin; (c) up to about 20 wt % of a thixotropic agent; and (d) up to about 20 wt % of a wetting agent. The use of more than one solvent, resin, thixotrope, and/or wetting agent is also envisioned. Although a variety of weight ratios of the solids portion to the vehicle system are envisioned, one embodiment includes a weight ratio of the solids portion to the vehicle system from about 20:1 to about 1:20, preferably about 15:1 to about 1:15, and more preferably about 10:1 to about 1:10.

Ethyl cellulose is a commonly used resin. However, resins such as ethyl hydroxyethyl cellulose, wood rosin, mixtures of ethyl cellulose and phenolic resins, polymethacrylates of lower alcohols and the monobutyl ether of ethylene glycol monoacetate can also be used. Solvents having boiling points (1 atm) from about 130° C. to about 350° C. are suitable. Widely used solvents include terpenes such as alpha- or beta-terpineol or higher boiling alcohols such as Dowanol® (diethylene glycol monoethyl ether), or mixtures thereof with other solvents such as butyl Carbitol® (diethylene glycol monobutyl ether); dibutyl Carbitol® (diethylene glycol dibutyl ether), butyl Carbitol® acetate (diethylene glycol monobutyl ether acetate), hexylene glycol, Texanol® (2,2,4-trimethyl-1,3-pentanediol monoisobutyrate), as well as other alcohol esters, kerosene, and dibutyl phthalate.

In one embodiment, the vehicle can contain organometallic compounds, for example those based on nickel, Ti, Ta, V, Sn, Mn, W, Co, phosphorus or silver, to modify the contact. N-DIFFUSOL® is a stabilized liquid preparation containing an n-type diffusant with a diffusion coefficient similar to that of elemental phosphorus. Various combinations of these and other solvents can be formulated to obtain the desired viscosity and volatility requirements for each application. Other dispersants, surfactants and rheology modifiers, which are commonly used in thick film paste formulations, may be included. Commercial examples of such products include those sold under any of the following trademarks: Texanol® (Eastman Chemical Company, Kingsport, Tenn.); Dowanol® and Carbitol® (Dow Chemical Co., Midland, Mich.); Triton® (Union Carbide Division of Dow Chemical Co., Midland, Mich.), Thixatrol® (Elementis Company, Hightstown N.J.), and Diffusol® (Transene Co. Inc., Danvers, Mass.); Santicizer® (Ferro Corporation, Cleveland, Ohio).

Among commonly used organic thixotropic agents is hydrogenated castor oil and derivatives thereof. A thixotrope is not always necessary because the solvent coupled with the shear thinning inherent in any suspension may alone be suitable in this regard. Furthermore, wetting agents may be employed such as fatty acid esters, e.g., N-tallow-1,3-diaminopropane di-oleate; N-tallow trimethylene diamine diacetate; N-coco trimethylene diamine, beta diamines; N-oleyl trimethylene diamine; N-tallow trimethylene diamine; N-tallow trimethylene diamine dioleate, and combinations thereof.

Other Additives

The paste compositions can optionally contain any other additives. In one embodiment, phosphorus is added to the paste composition in a variety of ways to reduce the resistance of the front contacts. For example, certain glasses can be modified with P₂O₅ in the form of a powdered or fitted oxide, or phosphorus can be added to the paste by way of phosphate esters and other organo-phosphorus compounds. More simply, when the conductive metal component is in the form of particles, phosphorus can be added as a coating to metal particles (e.g., silver and/or nickel particles) prior to making a paste. In such case, prior to pasting, the metal particles are mixed with liquid phosphorus and a solvent. For example, a blend of about 75 to about 95 wt % particles, about 5 to about 15 wt % solvent, and about 0.1 to about 20 wt % liquid phosphorus is mixed and the solvent evaporated. Phosphorus coated silver particles help ensure intimate mixing of phosphorus and particles in the pastes.

Other additives such as fine silicon or carbon powder, or both, can be added to the paste to control the metal reduction (e.g., silver reduction) and precipitation reaction. The metal precipitation at the interface or in the bulk glass can also be controlled by adjusting the firing atmosphere (e.g., firing in flowing N₂ or N₂/H₂/H₂O mixtures). However, no special atmosphere is required. Fine low melting metal additives (e.g., elemental metallic additives as distinct from metal oxides) such as Pb, Bi, In, Ga, Sn, Zn, Y and Ni, or alloys of each with at least one other metal can be added to provide a contact at a lower firing temperature, or to widen the firing window. Typically such metal additions are present at a rate of less than about 5 wt % of the conductive metal portion of the pastes herein. Organometallic compounds providing aluminum, barium, bismuth, magnesium, strontium, lithium, tantalum, titanium, and/or potassium can be used, such as, for example, the acetates, acrylates, methacrylate, formates, neodeconates, methoxides, ethoxides, methoxyethoxides, and stearates of the named metals. Metal silicate is also a suitable source of above metals. In one embodiment, the paste does not include additives (e.g., metal additives) containing Zn (e.g., elemental Zn).

A mixture of (a) glasses or a mixture of (b) glasses and crystalline additives or a mixture of (c) one or more crystalline additives can be used to formulate a glass component in the desired compositional range. The goal is to reduce the contact resistance and improve the solar cell electrical performance. For example, crystalline materials such as Bi₂O₃, Sb₂O₃, Sb₂O₅, In₂O₃, Ga₂O₃, SnO, MgO, ZnO, Cr₂O₃, Fe₂O₃, Pb₃O₄, PbO, PbO₂, SiO₂, ZrO₂, V₂O₅, Al₂O₃, B₂O₃, Y₂O₃, and Ta₂O₅ can be added to the glass component to adjust contact properties. The foregoing oxides can be added in glassy (i.e., non-crystalline) form as well. Combinations and reaction products of the aforementioned oxides can also be suitable to design a glass component with desired characteristics. For example, low melting lead silicates, either crystalline or glassy, formed by the reaction of PbO and SiO₂ such as 4PbO.SiO₂, 3PbO.SiO₂, 2PbO.SiO₂, 3PbO.2SiO₂, and PbO.SiO₂, either singly or in mixtures can be used to formulate a glass component. Other reaction products of the aforementioned oxides such as ZrO₂.SiO₂ can also be used. However, the total amounts of the above oxides will fall within the ranges specified for various embodiments disclosed elsewhere herein. In one embodiment, the glass component, the solid portion, and/or the paste do not include crystalline materials containing zinc (e.g., ZnO).

The glass frit can further contain oxides such as that of tellurium (TeO₂), Germanium (GeO₂), indium (In₂O₃), and/or gallium (Ga₂O₃) to increase both the size and quantity of the conductive metal islands as well as to decrease the flow temperatures of the glasses. In one embodiment, the glass component contains such oxides at about 0 mol % or more and about 15 mol % or less. In another embodiment, the glass component contains such oxides at about 0 mol % or more and about 10 mol % or less. In yet another embodiment, the glass component contains such oxides at about 0 mol % or more and about 5 mol % or less.

In another embodiment, the glass frit can further contain oxides of tantalum and molybdenum. The oxides of tantalum and molybdenum can reduce glass viscosity and surface tension of the glass during firing, facilitating better wetting of the wafer by the molten glass. In one embodiment, the glass component contains Ta₂O₅ at about 0 mol % or more and about 10 mol % or less and MoO₃ at about 0 mol % or more and about 3 mol % or less. In another embodiment, the glass component contains Ta₂O₅ at about 0 mol % or more and about 7 mol % or less and MoO₃ at about 0 mol % or more and about 2 mol % or less. In one embodiment, the glass component contains Ta₂O₅ at about 0 mol % or more and about 5 mol % or less and MoO₃ at about 0 mol % or more and about 1 mol % or less.

Kinetics of metal dissolution and precipitation from the glass compositions can be altered by the presence of alkali metal oxides. In that regard, the paste composition can further contain oxides of alkali metals, for example Na₂O, K₂O, and Li₂O, or combinations thereof. In one embodiment, the glass fit contains one or more of Na₂O, K₂O, and Li₂O at from about 0.1 mol % or more and about 15 mol % or less. In another embodiment, the glass frit contains one or more of Na₂O, K₂O, and Li₂O at about 0.1 mol % or more and about 10 mol % or less. In yet another embodiment, the glass frit contains one or more of Na₂O, K₂O, and Li₂O at from at about 0.1 mol % or more and about 5 mol % or less.

Paste Preparation

The paste composition can be formed by combining a conductive metal component, a glass binder, and a vehicle system that includes a vehicle and an organozinc compound and dispersing the conductive metal component and the glass binder in the vehicle system. The amount and type of vehicle utilized can be determined by the final desired formulation viscosity, fineness of grind of the paste, and the desired wet print thickness. In preparing compositions according to the invention, the particulate inorganic solids are mixed with the organic vehicle and dispersed with suitable equipment, such as a three-roll mill, to form a suspension, resulting in a composition for which the viscosity will be in the range of about 50 to about 200 kcps, preferably about 50 to about 130 kcps, at a shear rate of 9.6 sec⁻¹ as determined on a Brookfield viscometer HBT, spindle CP-51, measured at 25° C.

Printing and Firing of the Pastes

The aforementioned paste compositions can be used in a process to make a contact (e.g., fired front contact film) or other components, for example, for solar cells. The method of making the contact involves (1) applying the paste composition to a silicon substrate (e.g., silicon wafer), (2) drying the paste, and (3) heating (e.g., firing) the paste to sinter the metal of the paste and make contact to silicon. The printed pattern of the paste is heated or fired at a suitable temperature, such as about 650 to about 1000° C. furnace set temperature, or about 550 to about 850° C. wafer temperature. In one embodiment, the furnace set temperature is about 750 to about 960° C., and the paste is fired in air. The antireflective SiN_{X} layer is believed to be oxidized and corroded by the glass during firing and Ag/Si islands are formed on reaction with the Si substrate, which are epitaxially bonded to silicon. Firing conditions are chosen to produce a sufficient density of conductive metal/Si islands on the silicon wafer at the silicon/paste interface, leading to a low resistivity contact, thereby producing a high efficiency, high-fill factor solar cell.

A typical ARC is made of a silicon compound such as silicon nitride, generically SiN_{X:}H, This layer acts as an insulator, which tends to increase the contact resistance. Corrosion of this ARC layer by the glass component is hence a necessary step in front contact formation. Reducing the resistance between the silicon wafer and the paste can be facilitated by the formation of epitaxial metal/silicon conductive islands at the interface. That is, the metal islands on silicon assume the same crystalline structure as is found in the silicon substrate. When such an epitaxial metal/silicon interface does not result, the resistance at that interface becomes unacceptably high. The pastes and processes herein can make it possible to produce an epitaxial metal/silicon interface leading to a contact having low resistance under broad processing conditions—a minimum firing temperature as low as about 650° C., but which can be fired up to about 850° C. (wafer temperature).

The resulting fired front contact can include conductive metal at about 70 wt % or more and about 99.5 wt % or less of the fired front contact; a glass binder at about 0.5 wt % or more and about 15 wt % or less of the fired front contact; and zinc at about 0.001 wt % or more and about 20 wt % or less of the fired front contact. In one embodiment, the fired front contact includes zinc at about 0.01 wt % or more and about 15 wt % or less of the fired front contact. In another embodiment, the fired front contact includes zinc at about 0.05 wt % or more and about 10 wt % or less of the fired front contact.

Method of Front Contact Production

A solar cell contact according to the invention can be produced by applying any conductive paste disclosed herein to a substrate, for example, by screen-printing to a desired wet thickness, e.g., from about 30 to about 80 microns. Automatic screen-printing techniques can be employed using a 200-400 mesh screen. The printed pattern is then dried at 250° C. or less, preferably about 80 to about 250° C. for about 0.5-20 minutes before firing. The dry printed pattern can be fired for as little as 1 second up to about 30 seconds at peak temperature, in a belt conveyor furnace in air. During firing, the glass is fused and the metal is sintered.

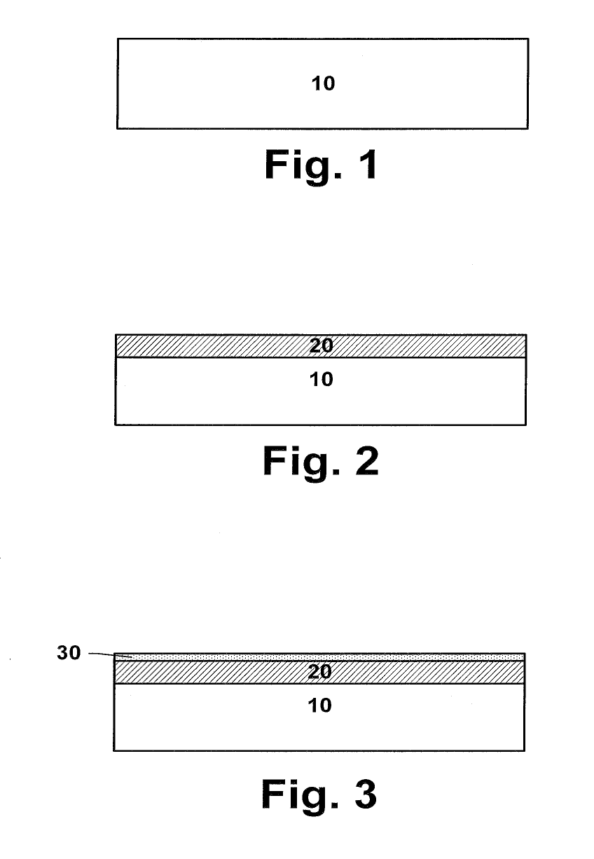

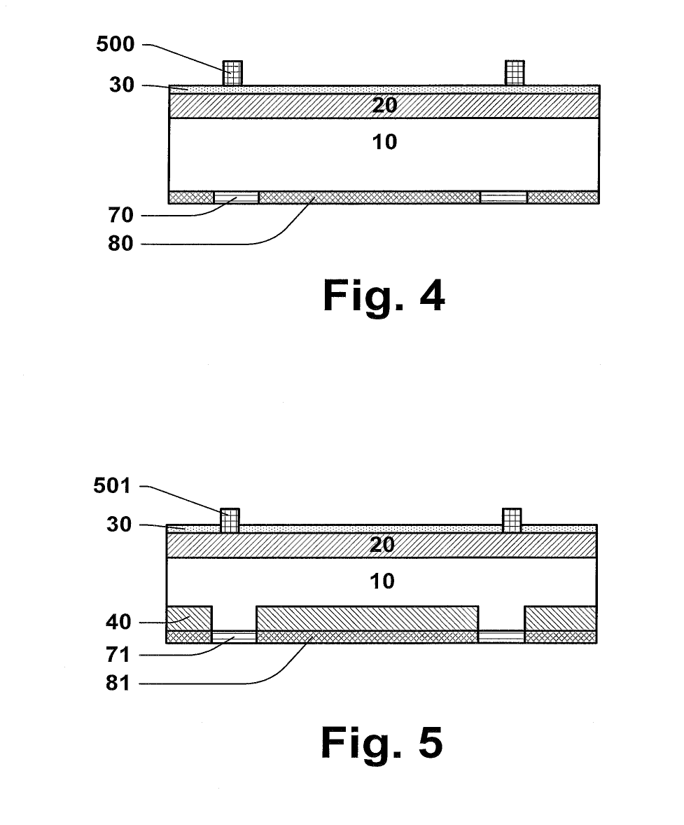

Referring now to FIGS. 1A-1E, one of many possible exemplary embodiments of making a solar cell front contact is illustrated. The solar cell front contact generally can be produced by applying the paste composition to a solar grade Si wafer. In particular, FIG. 1A schematically shows providing a substrate 10 of single-crystal silicon or multicrystalline silicon. The substrate can have a textured surface which reduces light reflection. In the case of solar cells, substrates are often used as sliced from ingots which have been formed from pulling or casting processes. Substrate surface damage caused by tools such as a wire saw used for slicing and contamination from the wafer slicing step are typically removed by etching away about 10 to 20 microns of the substrate surface using an aqueous alkali solution such as KOH or NaOH, or using a mixture of HF and HNO₃. The substrate optionally can be washed with a mixture of HCl and H₂O₂ to remove heavy metals such as iron that may adhere to the substrate surface. An antireflective textured surface is sometimes formed thereafter using, for example, an aqueous alkali solution such as aqueous potassium hydroxide or aqueous sodium hydroxide. This resulting substrate is depicted with exaggerated thickness dimensions, as a typical silicon wafer is about 160 to 200 microns thick.

FIG. 1B schematically shows that, when a p-type substrate is used, an n-type layer 20 is formed to create a p-n junction. A phosphorus diffusion layer is supplied in any of a variety of suitable forms, including phosphorus oxychloride (POCl₃), organophosphorus compounds, and others disclosed herein. The phosphorus source can be selectively applied to only one side of the silicon wafer. The depth of the diffusion layer can be varied by controlling the diffusion temperature and time, is generally about 0.3 to 0.5 microns, and has a sheet resistivity of about 40 to about 120 ohms per square. The phosphorus source can include phosphorus-containing liquid coating material such as phosphosilicate glass (PSG). The phosphorus source can be applied onto only one surface of the substrate by a process such as spin coating, where diffusion is effected by annealing under suitable conditions.

FIG. 1C illustrating forming an antireflective coating (ARC)/passivating film 30 over the substrate 10. The antireflective coating (ARC)/passivating film 30, which can be SiN_{X}, TiO₂ or SiO₂, is formed over the above-described n-type diffusion layer 20. Silicon nitride film is sometimes expressed as SiN_{X}:H to emphasize passivation by hydrogen. The ARC 30 reduces the surface reflectance of the solar cell to incident light, increasing the electrical current generated. The thickness of ARC 30 depends on its refractive index, although a thickness of about 700 to about 900 Å is suitable for a refractive index of about 1.9 to about 2.0. The ARC can be formed by a variety of procedures including low-pressure CVD, plasma CVD, or thermal CVD. When thermal CVD is used to form a SiN_{X} coating, the starting materials are often dichlorosilane (SiCl₂H₂) and ammonia (NH₃) gas, and film formation is carried out at a temperature of at least 700° C. When thermal CVD is used, pyrolysis of the starting gases at the high temperature results in the presence of substantially no hydrogen in the silicon nitride film, giving a substantially stoichiometric compositional ratio between the silicon and the nitrogen—Si₃N₄. Other methods of forming an ARC can be used.

FIG. 1D illustrates applying the subject paste composition 500 over the ARC film 30. The paste composition 500 includes a vehicle system that contains a vehicle and organozinc compounds. The paste composition can be applied by any suitable technique. For example, the paste composition can be applied by screen print on the front side of the substrate 10. The paste composition 500 is dried at about 125° C. for about 10 minutes. Other drying times and temperatures are possible so long as the paste vehicle is dried of solvent, but not combusted or removed at this stage.

FIG. 1D further illustrates forming a layer of back side pastes over the back side of the substrate 10. The back side paste layer can contain one or more paste compositions. In one embodiment, the first paste 70 facilitates forming a back side contact and a second paste 80 facilitates forming a p+ layer over the back side of the substrate. The first paste 70 can contain silver or silver/aluminum mixture and the second paste 80 can contain aluminum. An exemplary backside silver/aluminum paste is Ferro 3398 and backside silver paste is Ferro PS 33-610 or Ferro PS 33-612, commercially available from Ferro Corporation, Cleveland, Ohio. An exemplary commercially available backside aluminum/nickel paste is Ferro AL53-120 Standard, AL53-112, AL860, or AL5116, commercially available from Ferro Corporation, Cleveland, Ohio.

The back side paste layer can be applied to the substrate and dried in the same manner as the front pate layer 500. In this embodiment, the back side is largely covered with the aluminum paste, to a wet thickness of about 30 to 50 microns, owing in part to the need to form a thicker p+ layer in the subsequent process.

The wafer bearing the dried pastes is then fired in an infrared belt furnace, using an air atmosphere, at a furnace set temperature of about 650° C. to about 1000° C. for a period of from about one to several minutes. The firing is generally carried out according to a temperature profile that will allow burnout of the organic matter at about 300° C. to about 550° C., a period of peak furnace set temperature of about 650° C. to about 1000° C., lasting as little as about 1 second, although longer firing times as high as 1, 3, or 5 minutes are possible when firing at lower temperatures.

Firing is typically done in an air atmosphere. For example a six-zone firing profile can be used, with a belt speed of about 1 to about 6.4 meters (40-250 inches) per minute, preferably 5 to 6 meters/minute (about 200 to 240 inches/minute). In a preferred example, zone 1 is about 18 inches (45.7 cm) long, zone 2 is about 18 inches (45.7 cm) long, zone 3 is about 9 inches (22.9 cm) long, zone 4 is about 9 inches (22.9 cm) long, zone 5 is about 9 inches (22.9 cm) long, and zone 6 is about 9 inches (22.9 cm) long. The temperature in each successive zone is typically, though not always, higher than the previous, for example, 350-500° C. in zone 1, 400-550° C. in zone 2, 450-700° C. in zone 3, 600-750° C. in zone 4, 750-900° C. in zone 5, and 800-970° C. in zone 6. Naturally, firing arrangements having more than 3 zones are envisioned by the invention, including 4, 5, 6, 7, 8 or 9 zones or more, each with zone lengths of about 5 to about 20 inches and firing temperatures of 650 to 1000° C.

FIG. 1E illustrates sintering the metal portions of the paste 500 and fusing the glass frits of the paste 500, thereby making electrical contacts 501. As schematically shown in FIG. 1E, during firing, the front side paste 500 sinters and penetrates (i.e., fires through) the silicon nitride layer 30 and thereby makes electrical contact 501 with the n-type layer 20. The paste 80 containing aluminum over the back side melts and reacts with the silicon wafer 10, during firing, then solidifies to form a partial p+ layer 40 containing a high concentration of Al dopant. This layer is generally called the back surface field (BSF) layer, and helps to improve the energy conversion efficiency of the solar cell. A back electrode 81 can be formed by firing the paste 80. The paste 70 containing silver or silver/aluminum is fired becoming a back contact. The areas of the back side paste 71 can be used for tab attachment during module fabrication. Processes of making the pastes, solar cell contacts and solar cells disclosed herein are envisioned as embodiments of the invention.

### EXAMPLES

The following examples illustrate the subject invention. Unless otherwise indicated in the following examples and elsewhere in the specification and claims, all parts and percentages are by weight, all temperatures are in degrees Celsius, and pressure is at or near atmospheric pressure.

Polycrystalline silicon wafers, 15.6 cm×15.6 cm, thickness of 160 to 200 microns are coated with a silicon nitride antireflective coating. The sheet resistivity of these wafers is about 55-80 Ω/square. The paste compositions as indicated in Table 4 are formulated into pastes and the pastes are applied on the silicon wafers, respectively. In Table 4, the silver powder is a mixture of Ferro Ag powders with bimodal size distribution, with a medium particle size of 1 to 4 microns (83 wt %) and submicron Ag with a medium particle size of 0.2 to 0.6 microns. (1 wt %) all commercially available from Ferro Corporation, Cleveland, Ohio. The glass used is a lead glass with Tg of 350° C. to 550° C. The organo-metal compound is zinc based as in Table 4. The organic vehicle is a blend of Ethyl Cellulose Std. 4, 0.45 wt %; Ethyl Cellulose Std. 45, 1.28 wt %; Thixatrol® ST, 0.3 wt %; Triton® X-100, 0.18 wt %; N-Diffusol®, 0.5 wt %; Dowanol® DB, 8.45 wt %; and Terpineol, 3.84 wt %.

The paste compositions are printed using a 280 or 325 mesh screen with about 80 or 110 micron openings for front contact finger lines and about 2.5 mm spacing between the lines. Samples are dried at about 250° C. for about 3 minutes after printing the front contacts. The printed wafers are co-fired in air using a 6-zone infrared (IR) belt furnace from Despatch, with a belt speed of about 5 meters (200″) per minute, with temperature set points of 920 to 940° C. in the last zone. The zones are 18″, 18″, 9″, 9″, 9″ and 9″ long, respectively. The fired finger width for most samples is about 100 to about 160 microns, and the fired thickness is about 15 to 30 microns.

Electrical performance of the solar cells is measured with a solar tester, Model NCT-M-180A, NPC Incorporated, Dumont, N.J., under AM 1.5 sun conditions, in accordance with ASTM G-173-03. The results of this electrical testing are also presented in Table 4. EFF means cell efficiency (η); and R_{S} is previously defined.

TABLE 4
Pastes containing organo-Zn additives

| | | | | Organo-metal | | | |
|---|---|---|---|---|---|---|---|
| | | Silver | Organo-metal | compound | Organic | | |
| Paste | Glass | powder | compound | (%) | vehicle | RS | EFF |
| E1 | 4.9 | 84 | N/A | N/A | 11.1 | 1.000 | 1.000 |
| E2 | 4.9 | 84 | Zn(acac)2 | 0.2 | 10.9 | 0.953 | 0.996 |
| E3 | 4.9 | 84 | Zinc 2- | 1 | 10.1 | 0.969 | 1.001 |
| | | | ethylhexanoate/Zinc | | | | |
| | | | Neodecanoate | | | | |
| | | | mixture | | | | |
| E4 | 4.9 | 84 | Zinc 2- | 0.36 | 10.74 | 0.877 | 1.007 |
| | | | ethylhexanoate | | | | |

What has been described above includes examples of the subject invention. It is, of course, not possible to describe every conceivable combination of components or methodologies for purposes of describing the subject invention, but one of ordinary skill in the art may recognize that many further combinations and permutations of the subject invention are possible. Accordingly, the subject invention is intended to embrace all such alterations, modifications and variations that fall within the spirit and scope of the appended claims. Furthermore, the foregoing ranges (e.g., compositional ranges and conditional ranges) are preferred and it is not the intention to be limited to these ranges where one of ordinary skill in the art would recognize that these ranges may vary depending upon specific applications, specific components and conditions for processing and forming the end products. One range can be combined with another range. To the extent that the terms “contain,’ “have,” “include,” and “involve” are used in either the detailed description or the claims, such terms are intended to be inclusive in a manner similar to the term “comprising” as “comprising” is interpreted when employed as a transitional word in a claim. In some instances, however, to the extent that the terms “contain,’ “have,” “include,” and “involve” are used in either the detailed description or the claims, such terms are intended to be partially or entirely exclusive in a manner similar to the terms “consisting of” or “consisting essentially of” as “consisting of” or “consisting essentially of” are interpreted when employed as a transitional word in a claim.

1. A paste composition comprising a solid portion and a vehicle system, the solid portion comprising a conductive metal component at about 70 wt % or more and about 99.5 wt % or less of the solid portion and a glass binder comprising one or more glass frits at about 0.5 wt % or more and about 30 wt % or less of the solid portion, and the vehicle system comprising an organometallic compound comprising zinc.

2. The paste composition of claim 1, wherein the organometallic compound is fully dissolved in the vehicle system and the vehicle system is free of metal particles.

3. The paste composition of claim 1, wherein the paste composition comprises the organometallic compound comprising zinc at about 0.05 wt % or more and about 30 wt % or less of the paste composition.

4. The paste composition of claim 1, wherein the paste composition is free of solid particles that contain zinc.

5. The paste composition of claim 1, wherein the glass binder comprises a glass frit comprising:
55-88 wt % PbO,
0.5-15 wt % SiO₂, and
0.5-24 wt % (Al₂O₃+B₂O₃).

6. The paste composition of claim 5 wherein the glass frit further comprises 0.1-5 wt % (P₂O₅+Ta₂O₅).

7. The paste composition of claim 1, wherein the glass binder comprises a glass frit comprising:
65-90 wt % Bi₂O₃,
0.5-20 wt % SiO₂, and
0.5-24 wt % (B₂O₃+Al₂O₃).

8. The paste composition of claim 1, wherein the glass binder comprises a glass frit comprising:
30-62 wt % (B₂O₃+SiO₂),
2-22 wt % TiO₂, and
2-35 wt % (Li₂O+Na₂O+K₂O).

9. The paste composition of claim 8, wherein the glass frit further comprises 0.1-13 wt % (V₂O₅+Sb₂O₅).

10. A method of making a paste composition, comprising:
combining a conductive metal component, a glass binder, and a vehicle system comprising a vehicle and an organometallic compound comprising zinc; and
dispersing the conductive metal component and the glass binder in the vehicle system.

11. A contact formed on a silicon solar cell, said contact formed by firing the paste composition of claim 1.

12. A method of making a solar cell contact, comprising:
applying a paste composition to a silicon substrate, the paste comprising a solid portion and a vehicle system, the solid portion comprising a conductive metal component at about 70 wt % or more and about 99.5 wt % or less of the solid portion and a glass binder comprising one or more glass frits at about 0.5 wt % or more and about 30 wt % or less of the solid portion, and the vehicle system comprising an organometallic compound comprising zinc; and
heating the paste to sinter the conductive metal component and fuse the glass frit.
